(19) United States
(12) Patent Application Publication
(10) Pub. No.: US 2019/0341478 A1
(43) Pub. Date: Nov. 7, 2019

(54) Z2-FET STRUCTURE

(71) Applicants: STMicroelectronics (Crolles 2) SAS, Crolles (FR); STMicroelectronics SA, Montrouge (FR)

(72) Inventors: Hassan El Dirani, Grenoble (FR); Pascal Fonteneau, Theys (FR)

(21) Appl. No.: 16/398,417

(22) Filed: Apr. 30, 2019

(30) Foreign Application Priority Data
May 4, 2018 (FR) 1853860

(51) Int. Cl. H01L 29/739; H01L 29/161; H01L 29/08

(52) U.S. Cl. CPC H01L 29/7392; H01L 29/0834; H01L 29/161

(57) ABSTRACT

A Z2-FET-type structure includes a first front gate, a second front gate, a first back gate doped with p-type dopants, and a second back gate doped with n-type dopants. The structure may also include a buried insulating layer between the front gates and the back gates, an anode region, a cathode region, and an intermediate region separating the anode region and the cathode region.

### CROSS-REFERENCE TO RELATED APPLICATIONS

This application claims priority to French Patent Application No. 1853860, filed on May 4, 2018, which application is hereby incorporated herein by reference.

### TECHNICAL FIELD

The present disclosure concerns an electronic component, and more particularly an electronic component comprising a Z2-FET-type structure.

### BACKGROUND

A Z2-FET-type structure may be used to form a field effect diode.

One known Z2-FET is a forward biased p-i-n diode with the intrinsic channel partially covered by a front gate and the rest ungated.

### SUMMARY

An embodiment provides a Z2-FET-type structure comprising two front gates and two back gates, respectively of type P and of type N.

According to an embodiment, the two front gates each have a gate width smaller than 100 nm.

According to an embodiment, the two front gates each have a gate width on the order of 0.28 nm.

According to an embodiment, the two front gates are spaced apart by a distance shorter than 100 nm.

According to an embodiment, the structure is formed on a substrate comprising a buried insulating layer.

According to an embodiment, the buried insulating layer has a thickness on the order of 0.25 nm.

According to an embodiment, the structure further comprises an anode region, a cathode region, and a P-type doped intermediate region separating the anode region and the cathode region.

According to an embodiment, one of the front gate regions is insulated and positioned on top of and in contact with a first portion of the intermediate region, and another one of the front gate regions is insulated and positioned on top of and in contact with a second portion of the intermediate region.

According to an embodiment, the first portion of the intermediate region is in contact with the cathode region and the second portion of the intermediate region is in contact with the anode region.

According to an embodiment, the P-type doped back gate is positioned under the first portion of the intermediate region and the N-type doped back gate is positioned under the second portion of the intermediate region.

According to an embodiment, the intermediate region is made of strained silicon-germanium.

The foregoing and other features and advantages will be discussed in detail in the following non-limiting description of specific embodiments in connection with the accompanying drawings.

### BRIEF DESCRIPTION OF THE DRAWINGS

FIG. 1 is a cross-section view of an embodiment of a field-effect diode; and

FIG. 2 is a graph illustrating the potential along a portion of the diode of FIG. 1.

### DETAILED DESCRIPTION OF ILLUSTRATIVE EMBODIMENTS

The same elements have been designated with the same reference numerals in the different drawings. For clarity, only those steps and elements which are useful to the understanding of the described embodiments have been shown and are detailed.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings. Unless otherwise specified, the terms “approximately”, “substantially”, “about”, and “in the order of” are used herein to designate a tolerance of plus or minus 10%, preferably of plus or minus 5%, of the value in question.

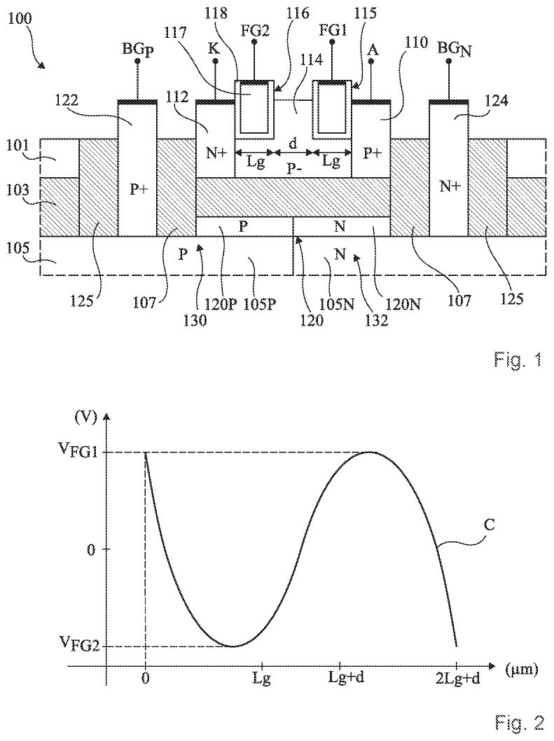

FIGS. 1 and 2 illustrate an embodiment of a field effect diode (FED). The operation of a field-effect diode is, for example, described in Yang et al.'s article entitled “Design and optimization of the SOI field effect diode (FED) for ESD protection” published in 2008 in Solid-State Electronics, volume 52, pages 1482 to 1485.

FIG. 1 is a cross-section view of an embodiment of a field-effect diode 100.

Diode 100 is formed inside and on top of a SOI (“Silicon On Insulator”) structure comprising a semiconductor layer 101 resting on an insulating layer 103, itself resting on a semiconductor support 105. Semiconductor layer 101 is generally made of silicon. Layer 101 has a thickness, for example, in the range from 3 to 25 nm, for example, on the order of 7 nm. Insulating layer 103 is currently called BOX (“Buried OXide”). Insulating layer 103 has a thickness, for example, in the range from 3 to 30 nm, for example, on the order of 25 nm. Semiconductor support 105 is generally made of silicon. Support 105 is divided into a P type doped portion 105P and an N-type doped portion 105N. Portion 105P is located to the left in FIG. 1A and portion 105N is located to the right in FIG. 1.

An active area is delimited in layer 101 by a peripheral insulating wall 107. Wall 107 extends from the upper surface of layer 101 to the upper surface of support 105 and surrounds the active area. The active area thus delimited comprises an anode region 110 and a cathode region 112 (or anode 110 and cathode 112) separated by an intermediate region 114. Anode region 110 is heavily P-type doped (P+) and is located above portion 105N of support 105, that is, is located on the right-hand side of the active area of layer 101 in FIG. 1. A contacting area is formed on the upper surface of anode region 110 and is coupled to a node A of application of an anode potential. Cathode region 112 is heavily N-type doped (N+) and is located above portion 105P of support 105, that is, is located on the left-hand side of the active area of layer 101 in FIG. 1.

A contacting area is formed on the upper surface of cathode region 112 and is coupled to a node K of application of a cathode potential. Intermediate region 114 is lightly P-type doped (P-) and is located between anode and cathode regions 110 and 112. As an example, intermediate region 114 may be made of strained silicon-germanium. In FIG. 1, regions 110, 112, and 114 are shown as having a thickness greater than layer 101, but as an example, the thickness of these regions may be on the order of the thickness of layer 101. Diode 100 further comprises two front gates 115 and 116 formed inside and on top of intermediate region 114. Each front gate 115, 116 is an insulated gate comprising a gate layer 117, for example, made of polysilicon, and an insulating layer 118.

Insulating layer 118 covers the lower surface and the lateral surfaces of gate layer 117. A contacting area is formed on the upper surface of gate layer 117 of each front gate 115, 116. The contacting area of the first front gate 115 is coupled to a node FG1 of application of a first front gate potential. The contacting area of second front gate 116 is coupled to a node FG2 of application of a second front gate potential.

First front gate 115 is positioned inside and on top of a portion of intermediate layer 114 on the side of anode no. Second front gate layer 116 is positioned inside and on top of intermediate layer 114 on the side of cathode 112. Each front gate 115, 116 has a gate width Lg, for example, smaller than approximately 200 nm, preferably smaller than 100 nm, for example, in the range from 20 to 100 nm, for example, on the order of 0.28 nm. Front gates 115, 116 are spaced apart by a distance d, for example, in the range from 20 to 150 nm, for example, on the order of 0.96 nm.

Diode 100 comprises a buried well 120 formed on a lower portion of insulating layer 103 in contact with the upper surface of support 105. Buried well 120 is divided into a P-type doped portion 120P and an N-type doped portion 120N. Portion 120P is positioned on top of and in contact with portion 105P of support 105. Portion 120N is positioned on top of and in contact with portion 105N of support 105. Buried well 120 is positioned under the active area of layer 101 and, more particularly, well 120 is delimited by insulating wall 107. In other words, buried well 120 extends all along the active area of layer 101.

Further, portions 105P and 120P are positioned on the side of cathode 112 and extend all the way to approximately half of intermediate region 114, at least along front gate 116. Portions 105N and 120N are positioned on the side of anode 110 and extend all the way to approximately half of intermediate region 114, at least along front gate 115. Support 105 and buried well 120 form the two back gates of diode 100. More particularly, portions 105P and 120P form a first back gate 130, and portions 105N and 120N form a second back gate 132. A heavily-doped P-type vertical well 122 (P+) is formed through layers 101 and 103. Well 122 extends from support 105 to the upper surface of layer 101, and more particularly portion 105P of support 105 at the upper surface of layer 101.

In FIG. 1, vertical well 122 protrudes from the upper surface of layer 101. A contacting area is formed on the upper surface of well 122 and is coupled to a node BGP of application of a potential. Well 122 is, for example, delimited on one side by insulating wall 107 and on the other side by another insulating wall 125. Well 122 enables to apply a potential to first back gate 130 of diode 100. A heavily-doped N-type vertical well 124 (N+) is formed through layers 101 and 103. Well 122 couples support 105 to the upper surface of layer 101, and more particularly portion 105N of support 105 to the upper surface of layer 101.

In FIG. 1, vertical well 124 protrudes from the upper surface of layer 101. A contacting area is formed on the upper surface of well 124 and is coupled to a node BGN of application of a potential. Well 124 is, for example, delimited on one side by insulating wall 107 and on the other side by another insulating wall 125. Well 122 enables to apply a potential to second back gate 132 of diode 100.

Diode 100 has a plurality of operating modes. To operate diode 100 like a conventional diode, a reference potential, preferably the ground, is applied to nodes FG1 and FG2, coupled to the two front gates 115 and 116. To operate diode 100 like a thyristor or SCR (“silicon controlled rectifier”) having an anode gate and a cathode gate, a positive potential is applied to node FG1, and a negative potential or the reference potential is applied to node FG2. Further, a negative potential is applied to node BGP and a positive potential is applied to node BGN. In such a configuration, the Z2-FET structure of diode 100 is controlled by voltage pulses applied to the anode and to the cathode such as a conventional Z2-FET-type structure.

FIG. 2 is a graph illustrating, via a curve C, the potential variation in intermediate region 114 of diode 100 of FIG. 1 during an SCR-type operation.

Abscissa 0 of the graph corresponds to the end on the cathode side of intermediate region 114 (that is, the left-hand end in FIG. 1) and abscissa 2Lg+d corresponds to the end on the anode side of intermediate region 114 (that is, the right-hand end of FIG. 1).

Curve C is obtained during an SCR-type operation of diode 100, during which:

a positive potential VFG1 is applied to the first front gate 115 via node FG1;

a negative potential VFG2 is applied to the second front gate 116 via node FG2;

a negative potential VBGP is applied to the first back gate 130 via node BGP; and

a positive potential VBGN is applied to the second back gate 132 via node BGN.

Potential VFG1 is, for example, smaller than 1 V, for example, smaller than 0.5 V, for example, on the order of 0.2 V. Potential VFG2 is, for example, greater than −1 V, for example, greater than −0.5 V, for example, on the order of −0.2 V. Potential VBGP is, for example, greater than −2 V, for example, on the order of −1 V or 0 V. Potential VBGN is, for example, smaller than 2 V, for example, on the order of 0 V or 1 V.

In the left-hand portion of intermediate region 114 positioned under second front gate 116, that is, the portion of curve C having its abscissa in the range from 0 to Lg, the potential rapidly decreases at the level of the edge of region 114 to decrease the level of negative potential VFG2.

In the median portion of intermediate region 114 which is topped neither with the first front gate 115 nor with the second front gate 116, that is, the portion of curve C having an abscissa in the range from Lg to Lg+d, the potential increases from negative potential VFG2 to positive potential VFG1.

In the right-hand portion of intermediate region 114 positioned under first front gate 115, that is, the portion of curve C having its abscissa in the range from Lg+d to 2Lg+d, the potential reaches the level of positive potential VFG1 and then rapidly decreases at the level of the edge of intermediate region 114.

Curve C shows a biasing inversion within intermediate region 114, such a biasing inversion being necessary to the operation of a Z2-FET-type structure. The use of two back gates with a different biasing enables to reinforce the biasing inversion within intermediate region 114. More particularly, applying a negative potential to the first back gate enables to reinforce the biasing the portion of the intermediate region positioned under the second front gate. Further, applying a positive potential to the second back gate enables to reinforce the biasing of the portion of the intermediate region positioned under the first front gate.

An advantage of this embodiment is that reinforcing the biasing inversion within intermediate region 114 makes possible the operation of the Z2-FET structure where the gates have a gate width, for example, on the order of 28 nm.

Another advantage of this embodiment is to be able to use diode 100 with low front gate biasing voltages, that is, voltages lower, in absolute value, than 0.5 V, for example, on the order of 0.2 V.

The following terms are used:

lightly-doped semiconductor layer designates a layer having a dopant atom concentration in the range from 1014 to 5×1015 atoms/cm3;

heavily-doped semiconductor layer designates a layer having a dopant atom concentration in the range from 1017 to 1018 atoms/cm33; and

very heavily-doped semiconductor layer designates a layer having a dopant atom concentration in the range from 1018 to 1020 atoms/cm3.

Specific embodiments have been described. Various alterations, modifications, and improvements will readily occur to those skilled in the art.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A Z2-FET-type structure comprising:
a first front gate;
a second front gate;
a first back gate doped with p-type dopants; and
a second back gate doped with n-type dopants.

2. The structure of claim 1, further comprising:
a buried insulating layer between the first and second front gates and the first and second back gates
an anode region;
a cathode region;
an intermediate region separating the anode region and the cathode region;
wherein the first front gate is insulated from and positioned on top of and in contact with a first portion of the intermediate region;
wherein the second front gate is insulated from and positioned on top of and in contact with a second portion of the intermediate region;
wherein the first portion of the intermediate region is in contact with the cathode region;
wherein the second portion of the intermediate region is in contact with the anode region;
wherein the first back gate is positioned under the first portion of the intermediate region; and
wherein the second back gate is positioned under the second portion of the intermediate region.

3. A Z2-FET-type structure comprising:
an anode region;
a cathode region;
an intermediate region separating the anode region and the cathode region;
a first front gate disposed at a top surface of the intermediate region adjacent the anode region;
a second front gate disposed at the top surface of the intermediate region adjacent the cathode region;
a first back gate disposed beneath a bottom surface of the intermediate region and underlying the anode region; and
a second back gate disposed beneath the bottom surface of the intermediate region and underlying the cathode region, the second back gate and the first back gate having opposite conductivity types.

4. The structure of claim 3, wherein the first and second front gates each have a gate width smaller than 100 nm.

5. The structure of claim 3, wherein the first and second front gates each have a gate width on the order of 28 nm.

6. The structure of claim 3, wherein the first and second front gates are spaced apart by a distance smaller than 100 nm.

7. The structure of claim 3, further comprising a buried insulating layer disposed between the intermediate region and the first and second back gates.

8. The structure of claim 7, wherein the buried insulating layer has a thickness on the order of 25 nm.

9. The structure of claim 3, wherein a first portion of the intermediate region is in contact with the cathode region and a second portion of the intermediate region is in contact with the anode region.

10. The structure of claim 9, wherein the second back gate is positioned under the first portion of the intermediate region and second back gate is positioned under the second portion of the intermediate region.

11. The structure of claim 3, wherein the intermediate region is made of strained silicon-germanium.

12. A semiconductor structure comprising:
a buried insulating layer;
a heavily doped n-type region overlying the buried insulating layer;
a heavily doped p-type region overlying the buried insulating layer and laterally spaced from the heavily doped n-type region;
a lightly doped p-type region overlying the buried insulating layer between the heavily doped n-type region and the heavily doped p-type region;
a first semiconductor region disposed at a surface of the lightly doped p-type region adjacent the heavily doped n-type region, the first semiconductor region electrically insulated from the lightly doped p-type region and from the heavily doped n-type region;
a second semiconductor region disposed at the surface of the lightly doped p-type region adjacent the heavily doped p-type region, the second semiconductor region electrically insulated from the lightly doped p-type region and from the heavily doped p-type region
a p-type region underlying the buried insulating layer beneath the first semiconductor region; and
an n-type region underlying the buried insulating layer beneath the second semiconductor region.

13. The structure of claim 12, wherein the first and second semiconductor regions are spaced apart by a distance smaller than 100 nm.

14. The structure of claim 12, wherein the buried insulating layer has a thickness on the order of 25 nm.

15. The structure of claim 12, wherein
the heavily doped p-type region functions as an anode region;
the heavily doped n-type region functions as a cathode region;
the first and semiconductor regions function as front gates; and
the p-type region and the n-type region function as back gates.

16. The structure of claim 15, wherein the front gates each have a gate width smaller than 100 nm.

17. The structure of claim 15, wherein the front gates each have a gate width on the order of 28 nm.

18. The structure of claim 15, wherein a first portion of the lightly doped p-type region is in contact with the cathode region and a second portion of the lightly doped p-type region is in contact with the anode region.

19. The structure of claim 18, wherein a first one of the back gates is positioned under the first portion of the lightly doped p-type region and a second one of the back gates is positioned under the second portion of the lightly doped p-type region.

20. The structure of claim 12, wherein the lightly doped p-type region is made of strained silicon-germanium.
